(19) United States
(12) Patent Application Publication
(10) Pub. No.: US 2018/0332708 A1
(43) Pub. Date: Nov. 15, 2018

(54) VERTICALLY EMBEDDED PASSIVE COMPONENTS

(71) Applicant: Intel Corporation, Santa Clara, CA (US)

(72) Inventors: William J. LAMBERT, Chandler, AZ (US); Mihir K. ROY, Chandler, AZ (US); Mathew J. MANUSHAROW, Phoenix, AZ (US)

(21) Appl. No.: 15/774,263

(22) PCT Filed: Dec. 26, 2015
(86) PCT No.: PCT/US2015/000396

§ 371 Date: May 7, 2018

(51) Int. Cl. H05K 1/18; H01L 25/16; H01L 23/498; H01L 21/48; H05K 3/00; H05K 3/40

(52) U.S. Cl. CPC H05K 1/185; H01L 25/16; H01L 23/49827; H01L 21/486; H05K 1/181; H05K 2201/10515; H05K 3/4038; H05K 2201/10015; H05K 2201/1003; H05K 2201/10651; H05K 3/0047

(57) ABSTRACT

Embodiments are generally directed to vertically embedded passive components. An embodiment of a device includes a semiconductor die; and a package coupled with the semiconductor die. The package includes one or more passive components connected with the semiconductor die, the one or more passive components being embedded vertically in the package substrate, each of the passive components including a first terminal and a second terminal. A first passive component is embedded in a through hole drilled in the package, the first terminal of the first passive component being connected to the semiconductor die by a via through an upper buildup layer on the package.

### TECHNICAL FIELD

Embodiments described herein generally relate to the field of electronic devices and, more particularly, to vertically embedded passive components.

### BACKGROUND

In electronic packages, there is a need for passive components, such as capacitors and inductors, in small areas. In particular, packages may include fine pitch BGA (Ball Grid Array) packages. In such packages, there often is insufficient room for the components on either side of the package. Further, the components are limited by factors including lands or bumps on the package, as well as by parasitic inductance or resistance factors.

Certain conventional methods for embedding components exist, but the conventional embedding methods add numerous needed processes, thus increasing the cost of the package. Currently, most components are embedded into the package using a process in which a laser or mechanical router routes a rectangular cavity into the core or a buildup layer of the package. The component is then placed in the cavity using a chip-shooter or a pick and place machine. The component is held in place in the cavity by an adhesive carrier until it is permanently fixed in place with epoxy. Connections to such component are established using vias, after which further processing resumes. This type of process is expensive, and occupies a large amount of area within a package.

The lowest cost-options for component embedding result in large component placement tolerances and strict rules about how many embedded components can be placed in a single cavity, while more accurate component placement requires a higher cost process that often eliminates the use of a package routing layer in the vicinity of the component.

### BRIEF DESCRIPTION OF THE DRAWINGS

Embodiments described here are illustrated by way of example, and not by way of limitation, in the figures of the accompanying drawings in which like reference numerals refer to similar elements.

FIG. 1 is an illustration of a device including vertically embedded passive components according to an embodiment;

FIG. 2 is an illustration of device including a vertically embedded passive component installed in a non-plated through hole according to an embodiment;

FIG. 3 is an illustration of a device including a vertically embedded passive component installed in a plated through hole according to an embodiment;

FIG. 4 is an illustration of a vertically embedded passive component installed in a non-plated through hole according to an embodiment;

FIG. 5 is an illustration of a vertically embedded passive component according to an embodiment;

FIG. 6 is an illustration of an alternative vertically embedded passive component according to an embodiment;

FIG. 7 is a flowchart to illustrate a process for fabrication of vertically embedded passive components according to an embodiment; and

FIG. 8 is an illustration of an embodiment of an apparatus or system including a package with vertically embedded passive components according to an embodiment.

### DETAILED DESCRIPTION

Embodiments described herein are generally directed to vertically embedded passive components.

For the purposes of this description, the following definitions apply:

“Passive device” or “passive component” refers to an electrical component that does not require a source of energy for operation. Passive devices include, but are not limited to, capacitors, inductors, resistors, and diodes.

“System on chip” or “SoC” refers to a chip or integrated circuit (IC) that includes all components of a system, including, for example, all components of a computer.

In some embodiments, an apparatus, system, or process provides for vertically embedded passive components. In some embodiments, cylindrical holes are drilled in a package core using a mechanical drill or a laser drill, and components are then inserted into these holes vertically. (As used herein, “vertical” refers to a z-direction for a package, which is perpendicular to the top and bottom surfaces of the package.) In some embodiments, the components are then connected to metal layers (described herein as the upper package buildup and the lower package buildup) on each side of the package core.

In some embodiments, a process provides a low cost method of embedding two-terminal components in a substrate, wherein the vertical embedding of a two-terminal passive component may operate to:

(1) Allow capacitors or inductors to be placed on, for example, fine-pitch BGA packages, wherein the collapsed ball height is too small to allow components to be placed on the ball side of the package and wherein there is limited or no room for die-side components.

(2) Allow components to be placed in areas of the package under the die where there are lands or bumps on the bottom of the package. For server products with very large dies it is difficult to decouple voltage rails in these areas with conventional technology because the voltage rails may be a very long distance from the nearest die-side or land-side capacitor location.

(3) Improve the electrical performance of the components that are being connected. Embedded capacitors may have reduced parasitic inductance, and the embedded inductors may have reduced series parasitic resistance.

In some embodiments, a process for embedding of passive components requires only the operation of drills to provide cavities for the embedding of the components. In this manner, the cost and complexity of a conventional routing process is eliminated, and complications regarding component alignment are minimized. The embedding process potentially allows for a much larger number of components to be embedded in a certain area, and for such embedding to be performed at a reduced cost.

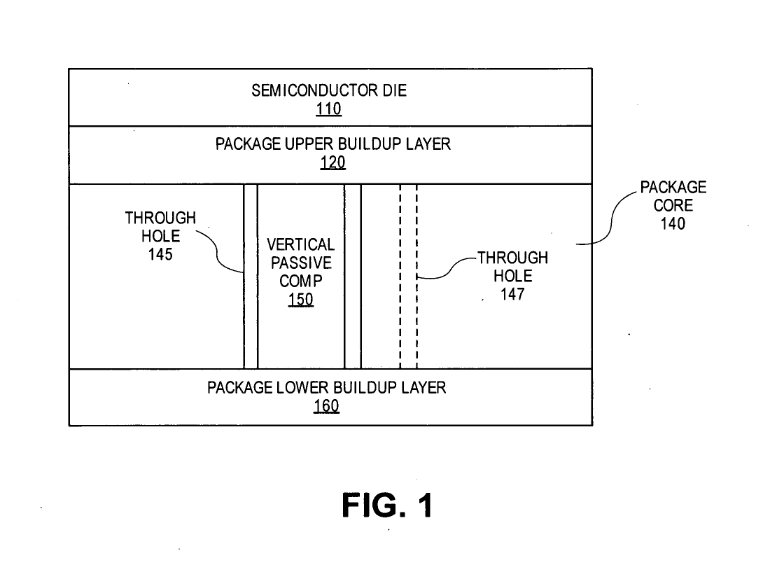

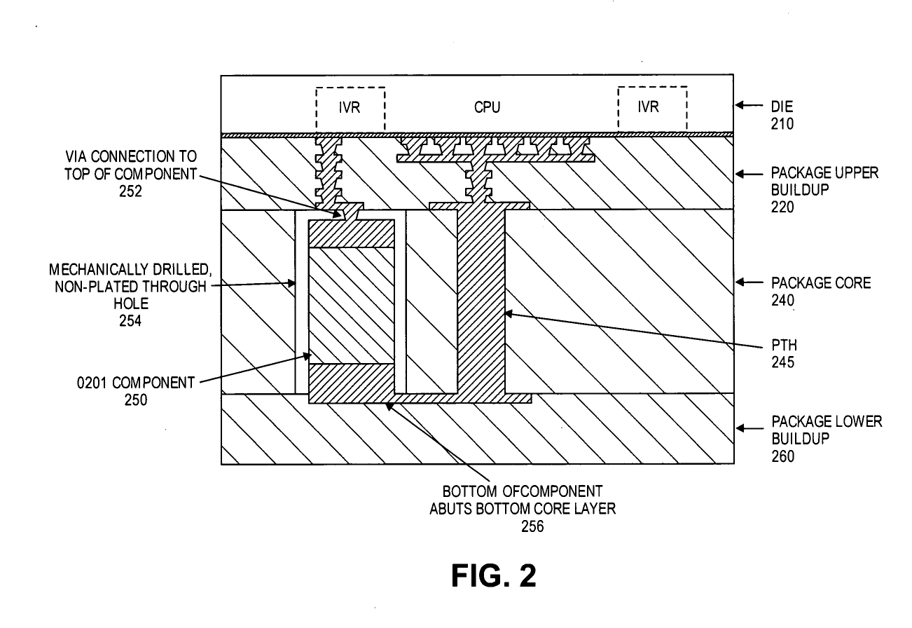

FIG. 1 is an illustration of a device including vertically embedded passive components according to an embodiment. As further illustrated in the embodiments shown in FIGS. 2-4, in some embodiments a semiconductor die 110, such as a central processing unit (CPU) die, is coupled with a package, shown as a package core 140 with a package upper buildup layer 120 and a package lower buildup layer 160. In some embodiments, a passive component 150 is vertically embedded in (or, stated in another way, embedded laterally through) the package core 140, the passive component 150 being embedded in a through hole 145 drilled through the package core 140.

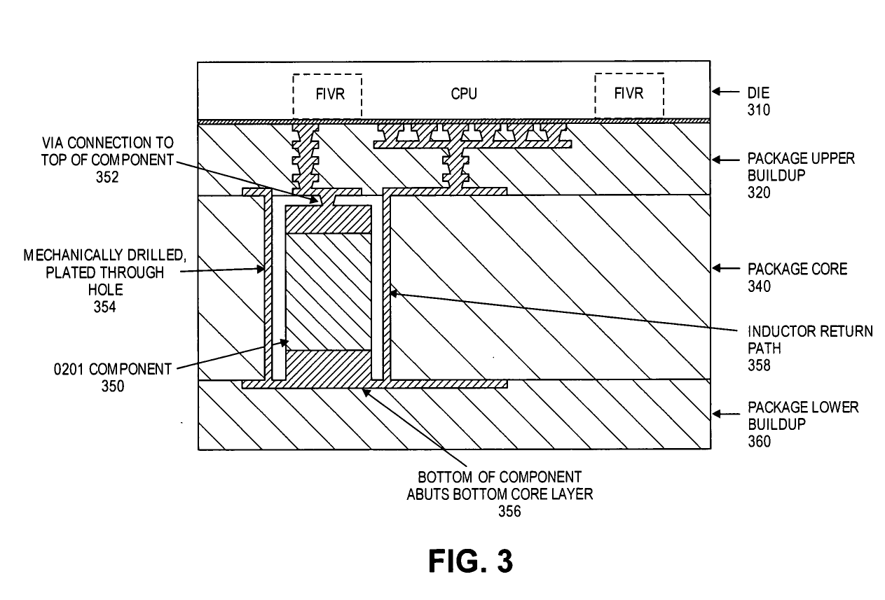

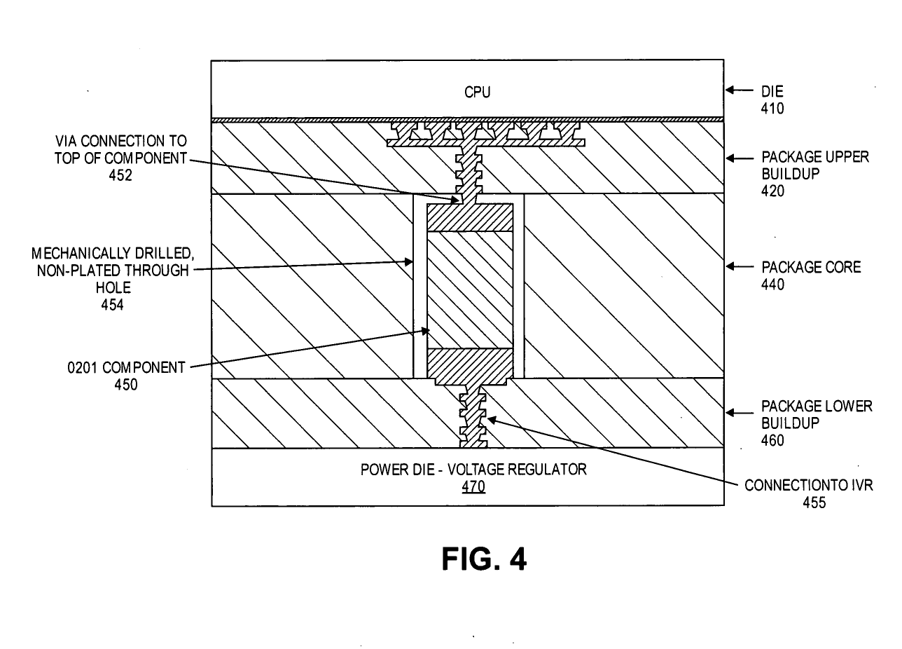

In some embodiments, a first (top) terminal of the vertically embedded passive component 150 is connected to the semiconductor die 110 using a via connection formed through the package upper buildup layer 120, as illustrated in FIGS. 2-4. In some embodiments, a second (bottom) terminal of the passive component 150 is connected by means of: a second through hole (a plated through hole) 147 (such as illustrated in FIG. 2) that is connected to the passive component 150; by means of a plated surface of the through hole 145 (such as illustrated in FIG. 3); or by means of a connection through the package lower buildup layer 160 (such as illustrated in FIG. 4).

FIG. 2 is an illustration of device including a vertically embedded passive component installed in a non-plated through hole according to an embodiment. As illustrated in FIG. 2, a semiconductor die 210, such as a CPU die, is coupled with a package, the package including a package core 240 with a package upper buildup layer 220 to which the die is coupled, and a package lower buildup layer 260 on an opposite side of the package. In some embodiments, a non-plated through-hole 254 is drilled through the package core 240 for the placement of a vertically embedded passive component 250, which in this instance is a 0201 component, thus having dimensions of 0.6 mm (millimeter) by 0.3 mm.

In some embodiments, a bottom of the component 250 is connected directly to the bottom core layer 256, whereas the top of the component is connected using a via 252, wherein the illustration assumes that there will be some mismatch between the height of the component 250 and the thickness of the package core 250. FIG. 2 further illustrates a plated through hole (PTH) 245 to provide a return path through the package core 240.

As illustrated in FIG. 2, the passive component 250 is an inductor connected in series for, in an example, an integrated voltage regulator (IVR), but this same configuration as provided in FIG. 2 may be alternatively used, for example, to connect one or more embedded capacitors to a power rail. As used herein, integrated voltage regulator refers to a switching or linear voltage regulator that is integrated on an IC die or IC package (i.e., consists of only circuits on the IC die or IC package). In this alternative example, the return PTHs could be shared between all of the capacitors on the power rail.

FIG. 3 is an illustration of a device including a vertically embedded passive component installed in a plated through hole according to an embodiment. As illustrated in FIG. 3, a semiconductor die 310, such as a CPU die, is coupled with a package, the package including a package core 340 with a package upper buildup layer 320, to which the semiconductor die 310 is coupled, and a package lower buildup layer 360 on an opposite side of the package. In some embodiments, a plated through-hole 354 is drilled through the package core 340 for the placement of a vertically embedded passive component 350, which in this instance is a 0201 component. Also illustrated is a via connection 352 formed through the package upper buildup layer 320 to the top of the component 350.

As illustrated in FIG. 3, the through-hole 354 has been plated before the component 350 is added. In the illustrated embodiment, the bottom of the component 350 is shorted to the wall of the PTH 354 by a bottom core layer 356, proving a low resistance return, as shown as inductor return path 358, to the top layers of the package. The embodiment illustrated in FIG. 3 allows for a compact implementation of vertically embedded components, with the X-Y area (the area of the top or bottom face) for a component being substantially reduced in comparison with conventional processes for embedding components.

FIG. 3 provide an illustration of a discrete IVR inductor. However embodiments are not limited to this implementation, and the illustrated version of vertical component embedding is also particularly useful for decoupling capacitors, as the plated hole 354 can be shared amongst all of the capacitors on a particular rail. In a particular example, if the polarity of the plated hole was alternated between VCCIN and VSS on an IVR-based package, the embedded capacitors could simultaneously act as the VCCIN and VSS PTHs for power routing from the package pins.

FIG. 4 is an illustration of a vertically embedded passive component installed in a non-plated through hole according to an embodiment. As illustrated in FIG. 4, a semiconductor die 410, such as a CPU die, is coupled with a package, the package including a package core 440 with a package upper buildup layer 420, to which the die is coupled, and a package lower buildup layer 460 on an opposite side of the package. In some embodiments, a non-plated through-hole 454 is drilled through the package core 440 for the placement of a vertically embedded passive component 450, which in this instance is a 0201 component. Also illustrated is a via connection 452 formed through the package upper buildup layer 420 to the top of the component 450 and a via connection 455 formed through the package lower buildup layer 460. In one particular example, the connection is to an integrated voltage regulator (IVR), the IVR being integrated into a power die 470.

As illustrated in FIG. 4, the apparatus represents an example in which a technology is used to power a CPU from the bottom of the package. In this case, the embedded inductor may be placed in series between the power die 470 and a CPU die 410. The apparatus allows, for example, to implement buck regulator inductors in a much smaller area than would be possible if discrete components were used.

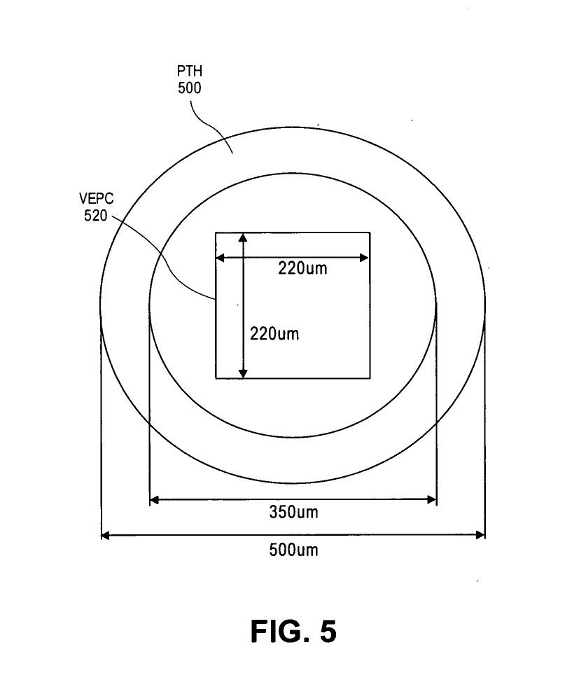

FIG. 5 is an illustration of a vertically embedded passive component according to an embodiment. FIG. 5 provides a top down view (viewing into an upper surface of a device) of a component 510, such as a 01005 component illustrated as 220 um (micrometers) by 220 um, that is vertically embedded in a plated through hole (PTH) 500. As shown in FIG. 5, the plated through hole 500 has an outside plating diameter of 500 um and an inside plating diameter of 350 um.

A via that is to be coupled to the top terminal of the component 520 is not shown. In the installation of such a component, the diameter of the drill determines the placement accuracy of the hole. However, as the terminal of the capacitor is relatively large compared to the diameter of the hole, the placement accuracy of the via to attach to the top pad is no likely to be a limiting factor.

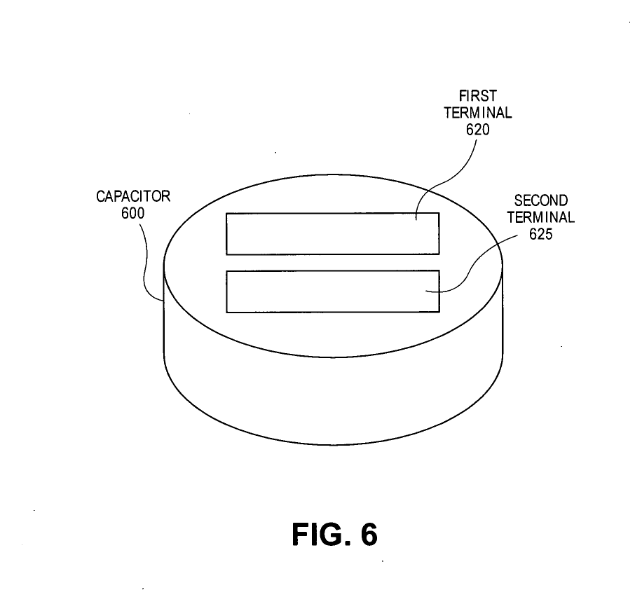

FIG. 6 is an illustration of an alternative vertically embedded passive component according to an embodiment. While current passive components are relatively long, which may limit vertical embedding to, for example, 400 um core or 700 um core packages, which are types of packages which remain in use for client desktop products and on many server products. However, the concept may be extended to thin core packaging through the implantation of alternative form factors for the passives components.

As illustrated in FIG. 6, an alternative “button” shaped capacitor 600 may be vertically embedded in a non-plated through hole, and would require only connections from the top layers of the package. As illustrated, the button shaped capacitor 600 may include top terminals such as the illustrated first terminal 620 and second terminal 625. However, embodiments are not limited to the implementation illustrated in FIG. 6, and may include other possible shapes and terminal placements.

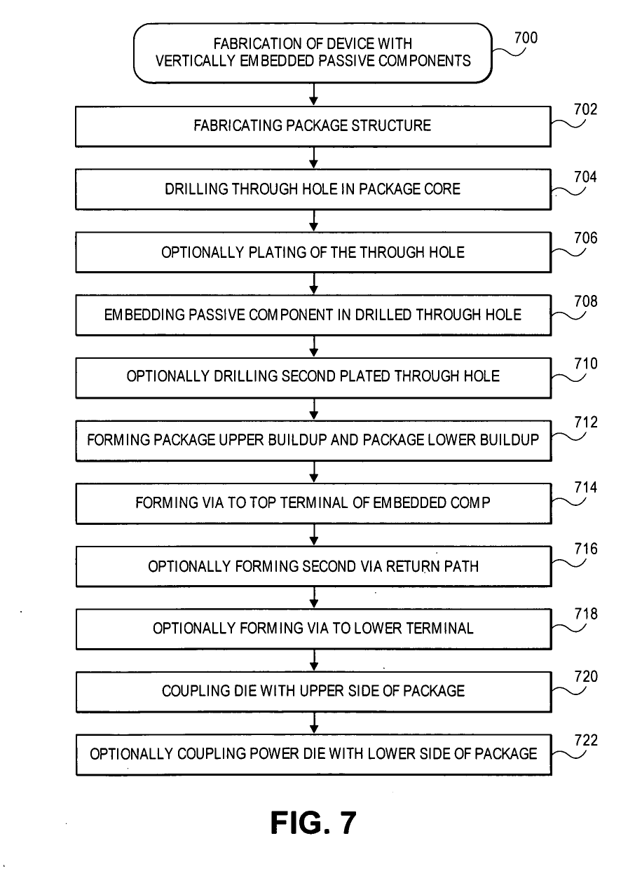

FIG. 7 is a flowchart to illustrate a process for fabrication of vertically embedded passive components according to an embodiment. In some embodiments, a process for fabrication of vertically embedded passive components 700 includes:

702: Fabricating a package structure by any known means.

704: Drilling a through hole in the package core.

706: Optionally plating the through hole, wherein choice of plating (as illustrated in FIG. 3) or non-plating (as illustrated in FIGS. 2 and 4) is dependent on the particular embodiment.

708: Embedding passive component in the drilled through hole.

710: Optionally drilling a second plated through hole in package core as return path for a non-plated through hole, and forming connection between embedded component and second through hole, such as illustrated in FIG. 2.

712: Forming package upper buildup layer and package lower buildup layer.

714: Forming via in the package upper buildup layer to top terminal of passive component.

716: Optionally forming second via in the package upper buildup layer to the return path in plate of PTH (as illustrated in FIG. 3) or second through hole (as illustrated in FIG. 2).

718: Optionally forming a via in the lower package buildup layer to lower terminal of the embedded component (as illustrated in FIG. 4).

720: Coupling a semiconductor die, such as a CPU die, with upper (first) side of package.

722: Optionally coupling power die with lower (second) side of package (as illustrated in FIG. 4).

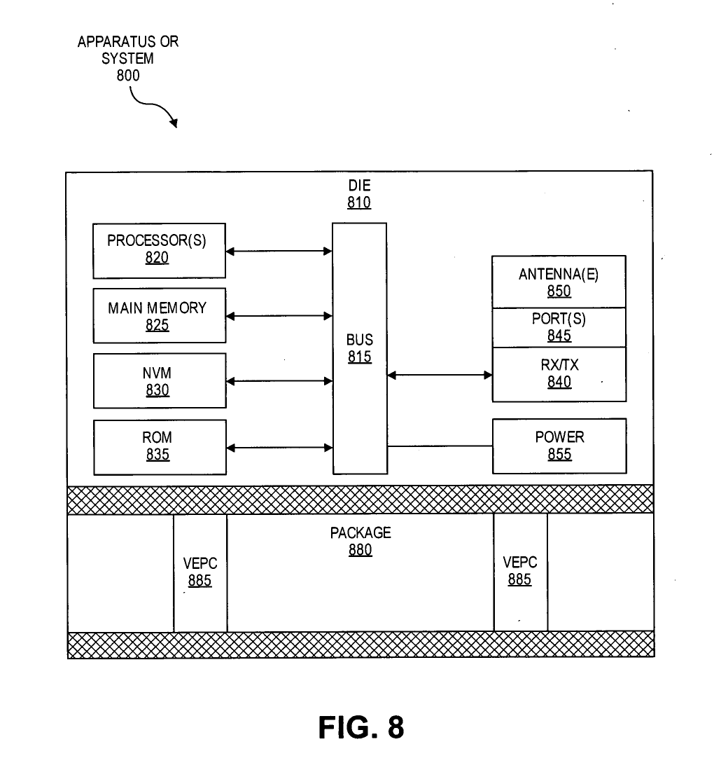

FIG. 8 is an illustration of an embodiment of an apparatus or system including a package with vertically embedded passive components according to an embodiment. In this illustration, certain standard and well-known components that are not germane to the present description are not shown.

In some embodiments, a system or apparatus 800 includes a semiconductor die 810 coupled with a package 880. In some embodiments, the package 880 includes one or more vertically embedded passive components 885, wherein the components may be coupled as illustrated in one or more of FIGS. 1-4.

In some embodiments, the semiconductor die 810 includes processing means such as one or more processors 820 (which may include a CPU) coupled to one or more buses or interconnects, shown in general as bus 815. The processors 820 may comprise one or more physical processors and one or more logical processors. In some embodiments, the processors may include one or more general-purpose processors or special-processor processors. The bus 815 is a communication means for transmission of data. The bus 815 is illustrated as a single bus for simplicity, but may represent multiple different interconnects or buses and the component connections to such interconnects or buses may vary. The bus 815 shown in FIG. 8 is an abstraction that represents any one or more separate physical buses, point-to-point connections, or both connected by appropriate bridges, adapters, or controllers.

In some embodiments, the semiconductor die 810 further comprises a random access memory (RAM) or other dynamic storage device or element as a main memory 825 for storing information and instructions to be executed by the processors 820. Main memory 825 may include, but is not limited to, dynamic random access memory (DRAM).

The semiconductor die 810 also may comprise a non-volatile memory (NVM) 830; and a read only memory (ROM) 835 or other static storage device for storing static information and instructions for the processors 835.

In some embodiments, the semiconductor die 810 includes one or more transmitters or receivers 840 coupled to the bus 815 to provide wired or wireless communications. In some embodiments, the semiconductor die 810 may include one or more antennae 850, such as dipole or monopole antennae, for the transmission and reception of data via wireless communication using a wireless transmitter, receiver, or both, and one or more ports 845 for the transmission and reception of data via wired communications. Wireless communication includes, but is not limited to, Wi-Fi, Bluetooth™, near field communication, and other wireless communication standards.

In some embodiments, the semiconductor die 810 may also comprise power source 855, which may include a battery, solar cell, a fuel cell, a charged capacitor, near field inductive coupling, or other system or device for providing or generating power in the semiconductor die 810. The power provided by the power source 855 may be distributed as required to elements of the semiconductor die 810.

In the description above, for the purposes of explanation, numerous specific details are set forth in order to provide a thorough understanding of the described embodiments. It will be apparent, however, to one skilled in the art that embodiments may be practiced without some of these specific details. In other instances, well-known structures and devices are shown in block diagram form. There may be intermediate structure between illustrated components. The components described or illustrated herein may have additional inputs or outputs that are not illustrated or described.

Various embodiments may include various processes. These processes may be performed by hardware components or may be embodied in computer program or machine-executable instructions, which may be used to cause a general-purpose or special-purpose processor or logic circuits programmed with the instructions to perform the processes. Alternatively, the processes may be performed by a combination of hardware and software.

Portions of various embodiments may be provided as a computer program product, which may include a computer-readable medium having stored thereon computer program instructions, which may be used to program a computer (or other electronic devices) for execution by one or more processors to perform a process according to certain embodiments. The computer-readable medium may include, but is not limited to, magnetic disks, optical disks, compact disk read-only memory (CD-ROM), and magneto-optical disks, read-only memory (ROM), random access memory (RAM), erasable programmable read-only memory (EPROM), electrically-erasable programmable read-only memory (EEPROM), magnet or optical cards, flash memory, or other type of computer-readable medium suitable for storing electronic instructions. Moreover, embodiments may also be downloaded as a computer program product, wherein the program may be transferred from a remote computer to a requesting computer.

Many of the methods are described in their most basic form, but processes can be added to or deleted from any of the methods and information can be added or subtracted from any of the described messages without departing from the basic scope of the present embodiments. It will be apparent to those skilled in the art that many further modifications and adaptations can be made. The particular embodiments are not provided to limit the concept but to illustrate it. The scope of the embodiments is not to be determined by the specific examples provided above but only by the claims below.

If it is said that an element “A” is coupled to or with element “B,” element A may be directly coupled to element B or be indirectly coupled through, for example, element C. When the specification or claims state that a component, feature, structure, process, or characteristic A “causes” a component, feature, structure, process, or characteristic B, it means that “A” is at least a partial cause of “B” but that there may also be at least one other component, feature, structure, process, or characteristic that assists in causing “B.” If the specification indicates that a component, feature, structure, process, or characteristic “may”, “might”, or “could” be included, that particular component, feature, structure, process, or characteristic is not required to be included. If the specification or claim refers to “a” or “an” element, this does not mean there is only one of the described elements.

An embodiment is an implementation or example. Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. It should be appreciated that in the foregoing description of exemplary embodiments, various features are sometimes grouped together in a single embodiment, figure, or description thereof for the purpose of streamlining the disclosure and aiding in the understanding of one or more of the various novel aspects. This method of disclosure, however, is not to be interpreted as reflecting an intention that the claimed embodiments requires more features than are expressly recited in each claim. Rather, as the following claims reflect, novel aspects lie in less than all features of a single foregoing disclosed embodiment. Thus, the claims are hereby expressly incorporated into this description, with each claim standing on its own as a separate embodiment.

In some embodiments, a device includes a semiconductor die; and a package coupled with the semiconductor die, the package including one or more passive components connected with the semiconductor die, the one or more passive components being embedded vertically in the package substrate, each of the passive components including a first terminal and a second terminal. In some embodiments, a first passive component is embedded in a through hole drilled in the package, the first terminal of the first passive component being connected to the semiconductor die by a via through an upper buildup layer on the package.

In some embodiments, the through hole is non-plated. In some embodiments, the second terminal of the first passive component is connected using a second through hole; the second through hole being plated and being connected to the second terminal of the first passive component. In some embodiments, wherein the second terminal of the first passive component is connected by a via through a lower buildup layer on the package, the lower buildup layer being on an opposite side of the package from the upper buildup layer.

In some embodiments, the through hole is plated. In some embodiments, the second terminal of the first passive component is connected by the plating of the plated through hole.

In some embodiments, the through hole is drilled using a mechanical drill.

In some embodiments, the semiconductor die includes a central processing unit (CPU).

In some embodiments, the one or more passive components include one or more capacitors, inductors, or both.

In some embodiments, the through hole is perpendicular to a surface of the package.

In some embodiments, the devices further including an integrated voltage regulator (IVR), wherein the first passive component is a first inductor connected with the IVR.

In some embodiments, a method for fabricating a device includes fabricating a package; drilling a through hole in the package; embedding a two-terminal passive component in the drilled through hole; forming a metal layer on a first side and a second side of the package; connecting a first terminal of the passive component to a via through the metal layer on the first side of the package; connecting a second terminal of the passive component to a return path; and coupling a semiconductor die with the first side of the package.

In some embodiments, the through hole is non-plated. In some embodiments, the method further includes drilling a second through hole in the package and plating the second through hole, wherein connecting the second terminal to a return path includes connecting the second terminal to the second through hole. In some embodiments, the method further includes forming a via through the metal layer on the second side of the package, wherein connecting the second terminal to a return path includes connecting the second terminal to the via through the metal layer on the second side of the package.

In some embodiments, the method further includes plating the through hole. In some embodiments, connecting the second terminal to a return path includes connecting the second terminal to the plating of the through hole.

In some embodiments, drilling the through hole includes drilling with a mechanical drill. In some embodiments, drilling the through hole includes drilling a hole in a z-direction in relation to the package.

In some embodiments, a system includes a central processing unit (CPU) die; an integrated voltage regulator (IVR); and a package coupled with the CPU die, the package including one or more passive components including a first inductor connected with the IVR, the one or more passive components being embedded vertically in the package substrate, each of the passive components including a first terminal and a second terminal. In some embodiments, wherein the first inductor is embedded in a through hole drilled in the package, a terminal of the first inductor being connected to the IVR by a via through an upper buildup layer or lower buildup layer on the package.

In some embodiments, the through hole is non-plated. In some embodiments, the first terminal of the first inductor is connected to the IVR through the upper layer build up and the second terminal of the first inductor is connected using a second through hole, the second through hole being plated and being connected to the second terminal of the first inductor. In some embodiments, a first terminal of the first inductor is connected to the CPU die through the upper layer build up and the second terminal of the first inductor is connected to the IVR by a via through a lower buildup layer on the package.

In some embodiments, the through hole is plated. In some embodiments, the first terminal of the first inductor is connected to the IVR through the upper layer build up and the second terminal of the first inductor is connected by the plating of the plated through hole.

What is claimed is:

1. A device comprising:
a semiconductor die; and
a package coupled with the semiconductor die, the package including one or more passive components connected with the semiconductor die, the one or more passive components being embedded vertically in the package substrate, each of the passive components including a first terminal and a second terminal;
wherein a first passive component is embedded in a through hole drilled in the package, the first terminal of the first passive component being connected to the semiconductor die by a via through an upper buildup layer on the package.

2. The device of claim 1, wherein the through hole is non-plated.

3. The device of claim 2, wherein the second terminal of the first passive component is connected using a second through hole, the second through hole being plated and being connected to the second terminal of the first passive component.

4. The device of claim 2, wherein the second terminal of the first passive component is connected by a via through a lower buildup layer on the package, the lower buildup layer being on an opposite side of the package from the upper buildup layer.

5. The device of claim 1, wherein the through hole is plated.

6. The device of claim 5, wherein the second terminal of the first passive component is connected by the plating of the plated through hole.

7. The device of claim 1, wherein the through hole is drilled using a mechanical drill.

8. The device of claim 1, wherein the semiconductor die includes a central processing unit (CPU).

9. A method for fabricating a device comprising:
fabricating a package;
drilling a through hole in the package;
embedding a two-terminal passive component in the drilled through hole;
forming a metal layer on a first side and a second side of the package;
connecting a first terminal of the passive component to a via through the metal layer on the first side of the package;
connecting a second terminal of the passive component to a return path; and
coupling a semiconductor die with the first side of the package.

10. The method of claim 9, wherein the through hole is non-plated.

11. The method of claim 10, further comprising drilling a second through hole in the package and plating the second through hole, wherein connecting the second terminal to a return path includes connecting the second terminal to the second through hole.

12. The method of claim 10, further comprising forming a via through the metal layer on the second side of the package, wherein connecting the second terminal to a return path includes connecting the second terminal to the via through the metal layer on the second side of the package.

13. The method of claim 9, further comprising plating the through hole.

14. The method of claim 13, wherein connecting the second terminal to a return path includes connecting the second terminal to the plating of the through hole.

15. The method of claim 9, wherein drilling the through hole includes drilling with a mechanical drill.

16. A system comprising:
a central processing unit (CPU) die;
an integrated voltage regulator (IVR); and
a package coupled with the CPU die, the package including one or more passive components including a first inductor connected with the IVR, the one or more passive components being embedded vertically in the package substrate, each of the passive components including a first terminal and a second terminal;
wherein the first inductor is embedded in a through hole drilled in the package, a terminal of the first inductor being connected to the IVR by a via through an upper buildup layer or lower buildup layer on the package.

17. The system of claim 16, wherein the through hole is non-plated.

18. The system of claim 17, wherein the first terminal of the first inductor is connected to the IVR through the upper layer build up and the second terminal of the first inductor is connected using a second through hole, the second through hole being plated and being connected to the second terminal of the first inductor.

19. The system of claim 18, wherein a first terminal of the first inductor is connected to the CPU die through the upper layer build up and the second terminal of the first inductor is connected to the IVR by a via through a lower buildup layer on the package.

20. The system of claim 16, wherein the through hole is plated.

21. The system of claim 20, wherein the first terminal of the first inductor is connected to the IVR through the upper layer build up and the second terminal of the first inductor is connected by the plating of the plated through hole.
